(19) United States
(12) Patent Application Publication
(10) Pub. No.: US 2016/0246171 A1
(43) Pub. Date: Aug. 25, 2016

(54) Method for Patterning Using a Composite Pattern

(71) Applicant: Tokyo Electron Limited, Tokyo (JP)

(72) Inventors: Anton J. deVilliers, Clifton Park, NY (US); Jeffrey Smith, Clifton Park, NY (US)

(21) Appl. No.: 15/048,033

(22) Filed: Feb. 19, 2016

Related U.S. Application Data
(60) Provisional application No. 62/119,145, filed on Feb. 21, 2015.

(51) Int. Cl. G03F 7/00; G03F 7/40; G03F 7/20; G03F 7/32; H01L 21/027; H01L 21/033

(52) U.S. Cl. CPC G03F 7/0035; H01L 21/0276; H01L 21/0335; H01L 21/0337; H01L 21/0338; G03F 7/20; G03F 7/32; G03F 7/40

(57) ABSTRACT

Techniques herein improved methods for patterning substrates. Techniques herein combine direct current superposition plasma processing with photolithographic patterning techniques. An electron flux or ballistic electron beam herein from plasma processing can induce cross linking in a given photoresist, which alters the photoresist to be resistant to subsequent light exposure and/or developer treatments. An initial relief pattern is treated to become insoluble to developing solvents. A second relief pattern is formed thereon using a same anti-reflective coating. The second relief pattern is also treated to become insoluble to developing solvents. A third relief pattern is then formed on the first and second relief patterns. The three relief patterns form a combined relief pattern without needing a memorization layer.

### CROSS REFERENCE TO RELATED APPLICATIONS

The present application claims the benefit of U.S. Provisional Patent Application No. 62/119,145, filed on Feb. 21, 2015, entitled “Method for Patterning Using a Composite Pattern,” which is incorporated herein by reference in its entirety.

### BACKGROUND OF THE INVENTION

This disclosure relates to patterning thin films and various layers on a substrate. Such patterning includes patterning for fabricating semiconductor devices within a photolithographic patterning scheme.

In material processing methodologies (such as photolithography), creating patterned layers comprises the application of a thin layer of radiation-sensitive material, such as photoresist, to a working surface of a substrate. This radiation-sensitive material is transformed into a patterned mask that can be used to etch or transfer a pattern into an underlying layer on a substrate. Patterning of the radiation-sensitive material generally involves exposure by a radiation source through a reticle (and associated optics) onto the radiation-sensitive material using, for example, a photo-lithography system such as a scanner or stepper tool. This exposure can then be followed by the removal of irradiated regions of the radiation-sensitive material or non-irradiated regions using a developing solvent depending on a photoresist tone and developer tone. This mask layer may comprise multiple sub-layers.

### SUMMARY

Conventional lithographic techniques for exposing a pattern of radiation or light onto a substrate have various challenges that limit a size of features exposed, and limit pitch or spacing between exposed features. One conventional technique to mitigate exposure limitations is that of using a double patterning approach to allow the patterning of smaller features at a smaller pitch than what is currently possible with conventional lithographic resolution. One approach to reduce the feature size is to use a conventional lithographic pattern and etch techniques twice on a same substrate (known as LELE—Litho/Etch/Litho/Etch) with one pattern offset from another, thereby forming more features spaced closely together to achieve a smaller feature size than would be possible by a single-exposure lithographic step. During LELE double patterning, the substrate is exposed to a first pattern and the first pattern is developed in the radiation-sensitive material. This first pattern is formed in the radiation-sensitive material and is transferred to an underlying layer using an etching process. This series of steps is repeated to create a second pattern, which is usually offset from the first pattern.

Another approach to reduce feature size is to use a conventional lithographic pattern on the same substrate twice followed by etch techniques (known as LLE—Litho/Litho/Etch), thereby using relatively larger scale patterns spaced closely together to achieve a smaller feature size than would be possible by a single exposure. During LLE double patterning, the substrate is exposed to a first light pattern and then the substrate is exposed to a second light pattern. A first latent pattern and a second latent pattern are developed in the radiation-sensitive material. A resulting topographic or relief pattern formed in the radiation-sensitive material can then be transferred to an underlying layer using an etching process, such as a plasma-based dry etching process.

Another approach to LLE double patterning includes a Litho/Freeze/Litho/Etch (LFLE) technique that uses an application of a freeze material on a first patterned layer to cause cross-linking therein, thus allowing the first patterned layer to withstand subsequent processing of patterning a second layer with a second pattern. A second LFLE freeze technique involves including a cross-linker additive material within the first layer (prior to exposure) instead of depositing a freeze material after development. This cross-linker is then thermally activated to increase resistivity to solvents. Thus this “freeze” refers to changing material properties of a patterned layer to be able to withstand other solvents or resists coated thereon. Conventional LFLE techniques, however, suffer from poor throughput and unacceptable defectivity, among other things.

Systems and methods disclosed herein include improved techniques for patterning substrates, including improvements to double patterning techniques. Techniques herein combine direct current superposition plasma processing with photolithographic patterning techniques. An electron flux or ballistic electron beam herein from plasma processing can induce cross linking in a given photoresist, which alters the photoresist to be resistant to subsequent light exposure and/or developer treatments. Plasma processing can also be used to add a protective layer of oxide on exposed surfaces of a first relief pattern, thereby further protecting the photoresist from a developing acid. By protecting an initial photoresist relief pattern from developing acid, a second relief pattern can be formed on and/or within (between structures of) the first photoresist relief pattern thereby doubling an initial pattern or otherwise increasing pattern density. This second relief pattern can then be treated like the first relief pattern. A third relief pattern can then be formed on the first and second relief patterns, which have been protected from being dissolved. This combined pattern can then be used for subsequent processing such as transferring the combined pattern into one or more underlying layers.

Embodiments herein include a patterning process that can be labeled a LFLFLE (litho/freeze/ litho/freeze/litho/etch) process. A first layer of radiation-sensitive material is provided on a substrate. A first exposure pattern is developed in the first layer of radiation-sensitive material. The first exposure pattern has been exposed via photolithography. Developing the first exposure pattern results in a first relief pattern. The first relief pattern is treated with a flux of electrons by coupling negative polarity direct current power to an upper electrode of a plasma processing system. The flux of electrons is accelerated from the upper electrode with sufficient energy to pass through a plasma and strike the substrate such that an exposed surface of the first relief pattern changes in physical properties. A second layer of radiation-sensitive material is formed on the substrate. A second exposure pattern in the second layer of radiation-sensitive material is developed. The second exposure pattern has been exposed via photolithography, wherein developing the second exposure pattern results in a second relief pattern. The second relief pattern is treated with a flux of electrons by coupling negative polarity direct current power to an upper electrode of the plasma processing system. The flux of electrons is accelerated from the upper electrode with sufficient energy to pass through the plasma and strike the substrate such that an exposed surface of the second relief pattern changes in physical properties. A third layer of radiation-sensitive material is formed on the substrate. A third exposure pattern in the third layer of radiation-sensitive material is developed. The third exposure pattern has been exposed via photolithography. Developing the third exposure pattern results in a third relief pattern such that the third relief pattern, the second relief pattern and the first relief pattern form a combined relief pattern.

Accordingly, techniques herein enable using three or more in plane photoresist layers/films with no memorization layer needed. Thus, a single anti-reflective coating can be used for exposing and patterning three different photoresist films.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete appreciation of various embodiments of the invention and many of the attendant advantages thereof will become readily apparent with reference to the following detailed description considered in conjunction with the accompanying drawings. The drawings are not necessarily to scale, with emphasis instead being placed upon illustrating the features, principles and concepts.

FIG. 1A is a schematic, cross-sectional view of a substrate segment showing a process sequence for patterning a substrate.

FIG. 1B is a schematic, top view of a substrate segment showing a process sequence for patterning a substrate.

FIG. 2 is a schematic, cross-sectional view of a substrate segment showing a process sequence for patterning a substrate.

FIG. 3A is a schematic, cross-sectional view of a substrate segment showing a process sequence for patterning a substrate.

FIG. 3B is a schematic, top view of a substrate segment showing a process sequence for patterning a substrate.

FIG. 4 is a schematic, cross-sectional view of a substrate segment showing a process sequence for patterning a substrate.

FIG. 5 is a schematic, cross-sectional view of a substrate segment showing a process sequence for patterning a substrate.

FIG. 6 is a schematic, top view of a substrate segment showing a process sequence for patterning a substrate.

FIG. 7 is a schematic, top view of a substrate segment showing a process sequence for patterning a substrate.

FIG. 8 is a schematic, top view of a substrate segment showing a process sequence for patterning a substrate.

FIG. 9 is a schematic, top view of a substrate segment showing a process sequence for patterning a substrate.

FIG. 10 is a schematic, top view of a substrate segment showing a process sequence for patterning a substrate.

FIG. 11 is a simplified schematic diagram showing a plasma processing system generating a flux of ballistic electrons.

### DETAILED DESCRIPTION

Systems and methods disclosed herein include improved techniques for patterning substrates, including improvements to double patterning techniques. Techniques herein combine direct current superposition plasma processing with photolithographic patterning techniques. An electron flux or ballistic electron beam herein from plasma processing can induce cross linking in a given photoresist, which alters the photoresist to be resistant to subsequent light exposure and/or developer treatments. Plasma processing can also be used to add a protective layer of oxide on exposed surfaces of a first relief pattern, thereby further protecting the photoresist from a developing acid. By protecting an initial photoresist relief pattern from developing acid, a second relief pattern can be formed on and/or within (between structures of) the first photoresist relief pattern thereby doubling an initial pattern or otherwise increasing pattern density. This second relief pattern can then be treated like the first relief pattern. A third relief pattern can then be formed on the first and second relief patterns, which have been protected from being dissolved. This combined pattern can then be used for subsequent processing such as transferring the combined pattern into one or more underlying layers.

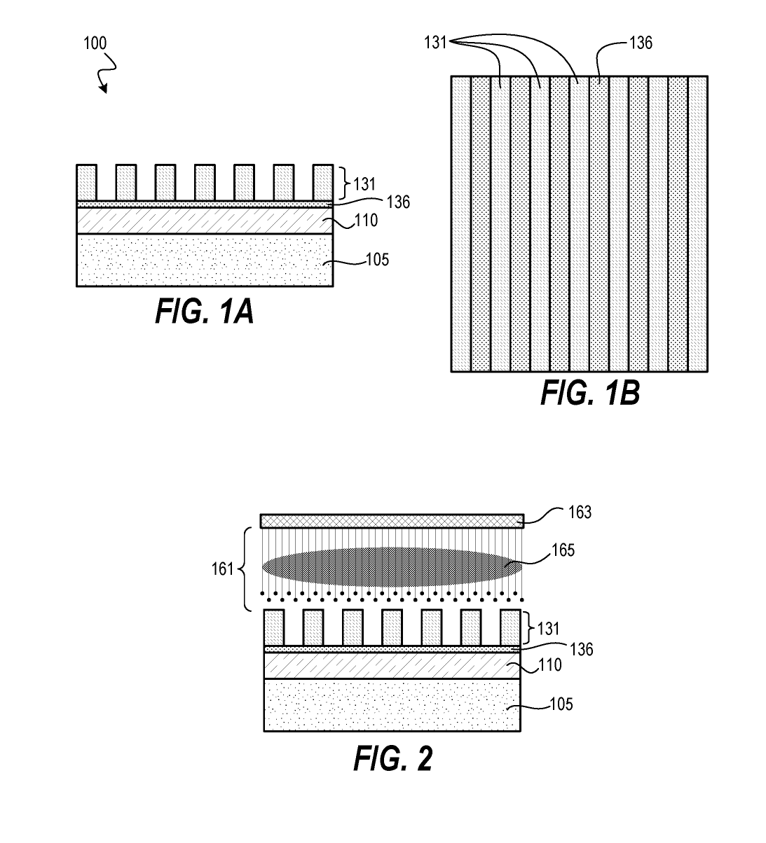

An example patterning process will now be described with reference to the accompanying figures. This patterning process, which can be labeled a LFLFLE (litho/freeze/ litho/freeze/litho/etch) process, includes an example DCS freeze process. One embodiment includes a method for patterning a substrate. Referring now to FIGS. 1A and 1 B, a first relief pattern 131 is formed on a substrate 100. This first relief pattern 131 is comprised of a first radiation-sensitive material, such as a photoresist. FIG. 1A is a side cross-sectional view of an example substrate segment. The first relief pattern 131 is shown positioned on anti-reflective coating 136, which is used to facilitate photolithographic exposure to form relief patterns. FIG. 1B is a top view of substrate 100 showing the first relief pattern 131 positioned on the anti-reflective coating 136. Substrate 100 includes an underlying layer 110 (which can be considered as a target layer) positioned on a base layer 105. The base layer 105 and underlying layer 110 can both include multiple layers, but for convenience is illustrated as having a single material. Note also that multiple layers can be included between the first relief pattern 131 and the underlying layer 110, such as organic planarization layers and other films to assist with fabrication. Various materials can be selected for these layers including silicon-containing materials, organic materials, or other materials such as those commonly used in the fabrication of integrated circuits.

Forming the first relief pattern 131 can include providing a first layer of radiation-sensitive material on the substrate, and then developing a first exposure pattern in the first layer of radiation-sensitive material. The first exposure pattern having been exposed via photolithography. Developing the first exposure pattern results in the first relief pattern 131. Such photolithographic techniques are known and can be executed using scanner/stepper tools and coater/developer tools, which are conventionally available.

The first relief pattern 131 is then caused to become insoluble to predetermined developing agents. In other words, the first relief pattern 131 is treated to resist being dissolved by solvents used to develop photoresist materials. For example, referring to FIG. 2, the first relief pattern 131 can be treated with a flux of electrons by coupling negative polarity direct current power to an upper electrode of a plasma processing system. A flux of electrons 161 is accelerated from the upper electrode 163 with sufficient energy to pass through plasma 165 and strike the substrate 100 such that an exposed surface of the first relief pattern 131 changes in physical properties. The upper electrode 163 can comprise silicon such that coupling negative polarity direct current power causes sputtering of silicon onto the first patterned layer creating a semi-conformal layer of silicon on the first relief pattern. The plasma 165 can be created in the processing chamber from a process gas flowed into the processing chamber. The process gas can include an inert gas and hydrogen, a noble gas and nitrogen, and other gas combinations.

The change in physical properties can include increased cross-linking of the exposed surface such that the exposed surface of the first relief pattern 131 increases in resistance to particular developing chemicals. For example, such cross-linking can cause the first relief pattern 131 to become insoluble to given chemical solvents.

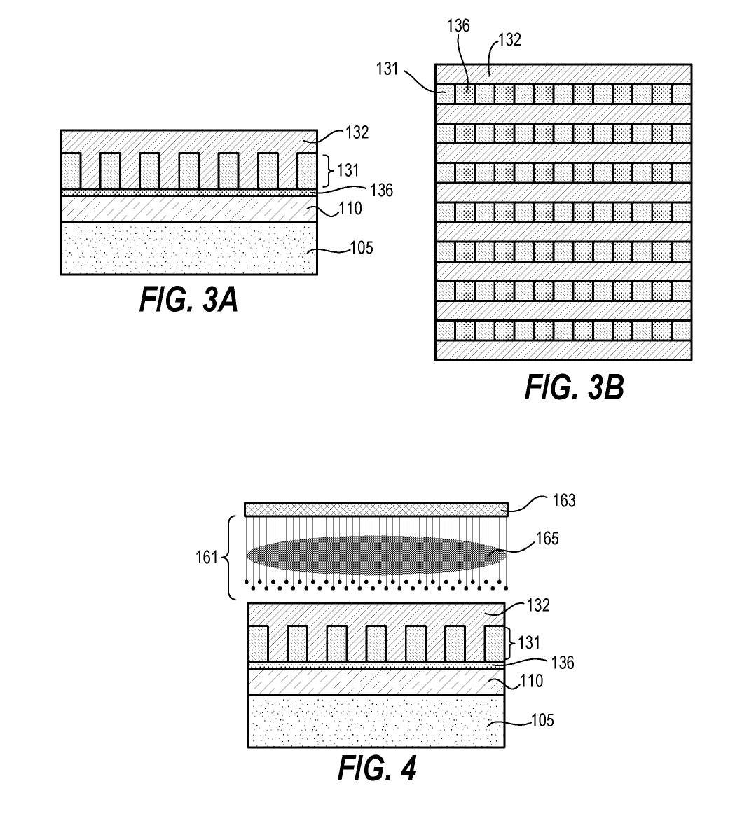

Referring now to FIGS. 3A and 3B, a second relief pattern 132 is formed on the substrate 100. This second relief pattern 132 is comprised of a second radiation-sensitive material, such as a photoresist. FIG. 3A is a side cross-sectional view of the example substrate segment, while FIG. 3B is a top view of the example substrate segment. With the first relief pattern 131 being insoluble to developing agents, the second relief pattern 132 can be formed in plane with the first relief pattern. Note that in FIG. 3A, second relief pattern 132 extends into trenches or openings defined by the first relief pattern. Thus, at least a portion of the second relief pattern 132 is in a same plane or level as the first relief pattern 131. In other embodiments, a planarization layer can be deposited over the first relief pattern 131 prior to forming the second relief pattern 132, but the same anti-reflective coating used to for the first relief pattern can be used in forming the second relief pattern.

Forming the second relief pattern 132 can include forming a second layer of radiation-sensitive material on the substrate, and then developing a second exposure pattern in the second layer of radiation-sensitive material. The second exposure pattern having been exposed via photolithography. Developing the second exposure pattern results in the second relief pattern 132.

The second relief pattern 132 is then caused to become insoluble to predetermined developing agents. In other words, the second relief pattern 132 is treated to become resistant to being dissolved by solvents used to develop photoresist materials. FIG. 4 illustrates the second relief pattern 132 being treated with a flux of electrons by coupling negative polarity direct current power to an upper electrode of a plasma processing system. Thus, a same treatment used to render the first relief pattern 131 insoluble can be executed again for the second relief pattern 132.

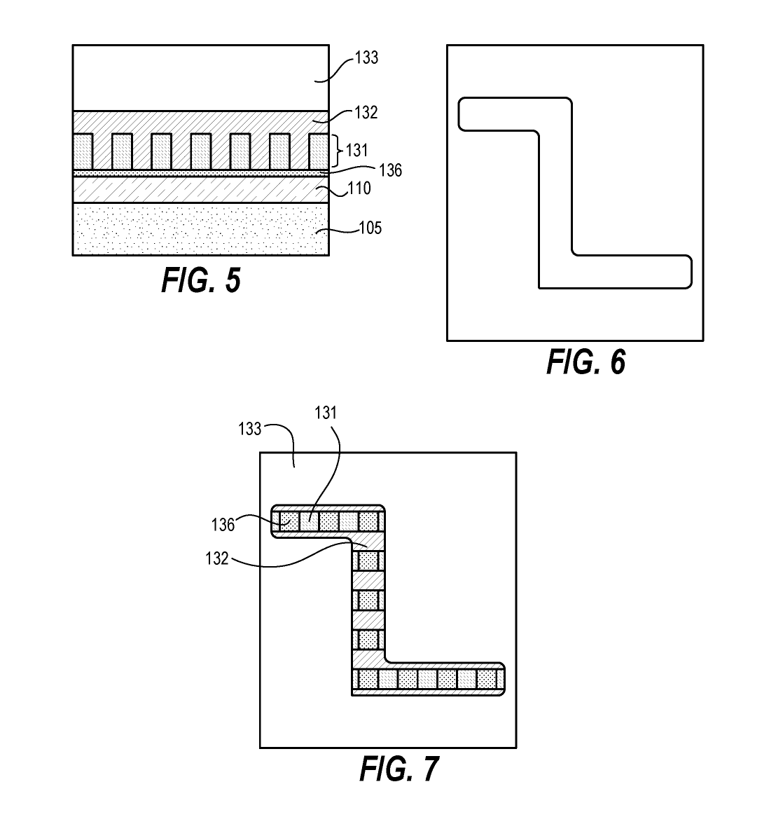

A third relief pattern 133 is then formed on the substrate 100. This third relief pattern 133 can be formed in plane with the first relief pattern 131 and the second relief pattern 132 to form a combined relief pattern. FIG. 5 shows a side cross-sectional view of forming a third layer of radiation-sensitive material on the substrate. FIG. 6 shows a top view of a third exposure pattern (latent pattern) that has been exposed via photolithography. For this particular example, the latent pattern is illustrated as a line with two ninety degree turns. This third exposure pattern is then developed to result in the third relief pattern 133. FIG. 7 shows an example result after developing this third exposure pattern. Note that the third relief pattern 133 defines a subset of openings from the first two relief patterns that are accessible to directional etchants. The first two relief patterns, in this example, are essentially intersecting sets of lines that define an array of contact openings. The third relief pattern then defines which contact openings are uncovered or accessible. Note that anti-reflective coating 136 is visible in FIG. 7 through the combined relief pattern.

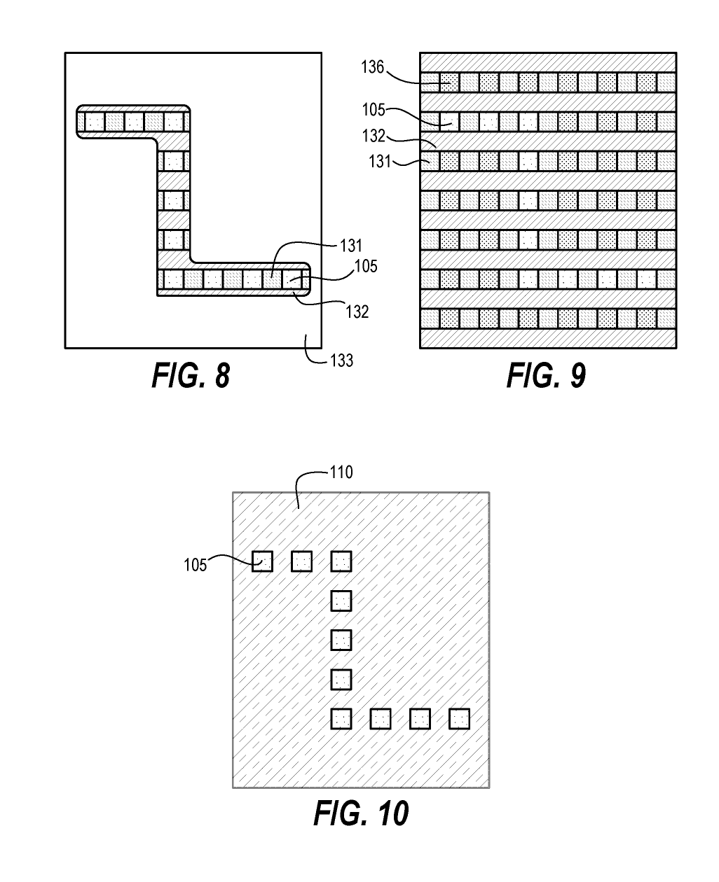

With a combined relief pattern created, additional fabrication steps can be executed. One additional step can include transferring the combined relief pattern into one or more underlying layers. This can be executed, for example, with a directional, plasma-based dry etching step. FIG. 8 is a top view that shows an example result of this step. Note that anti-reflective coating 136 and underlying layer 110 have been etched through and now base layer 105 is visible from the top view. FIG. 9 illustrates this example substrate segment with third relief pattern 133 having been removed, to illustrate that only a subset of defined holes having been transferred into an underlying layer. FIG. 10 is a top view of the substrate with the remaining relief patterns having been removed as well as the anti-reflective coating 136. The example result is then underlying layer 110 having a pattern of holes, which could be, contact openings. Note that the designs of the relief patterns used herein are just one example. It should be readily apparent to those of skill in the art than any number of pattern configurations can be used to create a desired pattern. For example, the combined pattern can include features formed from one or more antispacer fabrication processes, pitch density multiplying techniques, and so forth.

In other embodiments, the first relief pattern can be comprised of a negative tone developer resist, positive tone developer resist, or alcohol-based resist. Likewise, the second relief pattern can be selected from various available resists including negative tone developer resist, positive tone developer resist, and alcohol-based resists. Rendering the first and second relief patterns insoluble enable using resists of a same type. For example, the first relief pattern can be a negative tone developer resist, and the second relief pattern can also be a negative tone developer resist. In other embodiments, the third relief pattern, the second relief pattern and the first relief pattern can all be in plane with each other. Also, a single anti-reflective coating can be used for the first exposure pattern, the second exposure pattern and the third exposure pattern. Re-using the anti-reflective coating can benefit substantially on time and expenditure on different films that would be conventionally needed for separately memorizing three different relief patterns into a memorization layer.

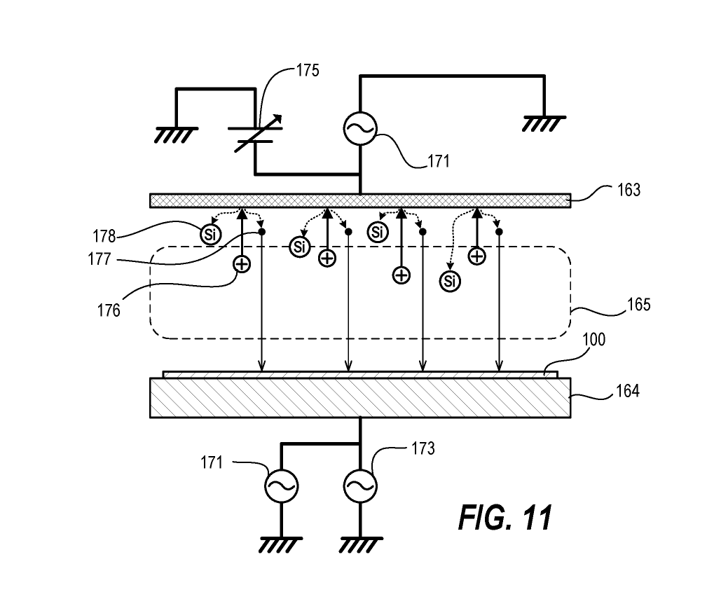

Regarding rendering photoresist patterns insoluble, FIG. 11 shows more detail on creating a flux of electrons to change solubility properties of one or more photoresist relief patterns. FIG. 11 is a simplified schematic diagram of the result of superimposing negative polarity direct current on upper electrode 163, also described as direct current superposition (DCS). FIG. 11 includes a cross-sectional schematic of an example plasma processing system. Substrate 100 is positioned on lower electrode 164. Source radio frequency power 171 can be applied to either the upper electrode 163, or to the lower electrode 164. A bias radio frequency power 173 can be applied to the lower electrode to enable anisotropic etching when desired. DC power source 175 is configured to apply negative direct current power to the upper electrode 163.

The DCS treatment step can be executed within a capacitively coupled plasma (CCP) processing system, which typically forms plasma between two opposing, parallel plates (an upper electrode and a lower electrode). Typically a substrate rests on the lower electrode or a substrate holder positioned just above the lower electrode. Applying negative DC to an upper electrode then draws positively charged ions 176 (positively charged species) toward the upper electrode 163. This upper electrode 163 is made of, or coated with, a desired conductive material. Typically this conductive material is silicon, but other materials can be used (such as germanium) for specific applications.

When negative DC voltage is applied to the upper electrode, the upper electrode attracts positively charged ions 176 within plasma 165 that exists between the parallel plate electrodes. The positively charged ions 176 that are accelerated toward the upper electrode 163 have sufficient energy that upon striking the upper electrode the positively charged ions 176 produce secondary electrons 177 as well as sputtering some silicon atoms 178. The secondary electrons produced then get accelerated by the negative DC voltage (accelerated away from the upper electrode 163) and have sufficient energy to travel entirely through the plasma 165 and strike the substrate below. These electrons can be referred to as ballistic electrons.

The electron flux (ballistic electrons or e-beam) can produce dangling bonds of various resist chemical groups, which can enable cross-linking of the resist, thereby changing the resist's physical properties. The electron flux can be sufficient to increase cross-linking in the first relief pattern 131. A semi-conformal layer, such as an oxide layer, can be formed from the DCS treatment. Initially, a layer of pure silicon develops on the substrate surface because of silicon sputtering, but as soon as the substrate leaves the etch processing chamber into an oxygen environment (out of the vacuum chamber), the pure silicon layer can immediately or quickly oxidize and form a silicon oxide layer. Embodiments can include exposing the semi-conformal layer of silicon to an oxygen-containing environment such that the semi-conformal layer 138 of silicon becomes silicon oxide. The silicon oxide layer can then act as a protective layer. The result is that the relief patterns treated accordingly are protected from developing chemicals used for dissolving and removing resists, and also from actinic radiation.

Accordingly, techniques herein enable using three or more in plane photoresist layers/films with no memorization layer needed. Conventional techniques would use six different films that are built up in pairs. This can include an anti-reflective coating (ARC) and a transfer film, then another anti-reflective coating and transfer film pair, and then yet another anti-reflective coating and transfer film. The ARC must be below the resist, so there is deposition of an ARC and a transfer film. After etching through the transfer film, the ARC needs to be rebuilt, and then new photoresist deposited on top. This photoresist is then patterned and then etched down into another transfer film. These steps can be repeated six times over and eventually pushed down into a seventh film, which is a combined transfer film, which can then be transferred into a hardmask. With techniques herein, however, all of this is executed in-plane in one layer, with only one ARC used.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. A method for patterning a substrate, the method comprising:
providing a first layer of radiation-sensitive material on a substrate;
developing a first exposure pattern in the first layer of radiation-sensitive material, the first exposure pattern having been exposed via photolithography, wherein developing the first exposure pattern results in a first relief pattern;
treating the first relief pattern with a flux of electrons by coupling negative polarity direct current power to an upper electrode of a plasma processing system, the flux of electrons being accelerated from the upper electrode with sufficient energy to pass through a plasma and strike the substrate such that an exposed surface of the first relief pattern changes in physical properties;
forming a second layer of radiation-sensitive material on the substrate;
developing a second exposure pattern in the second layer of radiation-sensitive material, the second exposure pattern having been exposed via photolithography, wherein developing the second exposure pattern results in a second relief pattern;
treating the second relief pattern with the flux of electrons by coupling negative polarity direct current power to the upper electrode of the plasma processing system, the flux of electrons being accelerated from the upper electrode with sufficient energy to pass through the plasma and strike the substrate such that an exposed surface of the second relief pattern changes in physical properties;
forming a third layer of radiation-sensitive material on the substrate;
developing a third exposure pattern in the third layer of radiation-sensitive material, the third exposure pattern having been exposed via photolithography, wherein developing the third exposure pattern results in a third relief pattern such that the third relief pattern, the second relief pattern and the first relief pattern form a combined relief pattern.

2. The method of claim 1, wherein the first relief pattern is selected from the group consisting of negative tone developer resist, positive tone developer resist, and alcohol-based resist; and
wherein the second relief pattern is selected from the group consisting of negative tone developer resist, positive tone developer resist, and alcohol-based resist.

3. The method of claim 1, wherein the first relief pattern is selected from a negative tone developer resist, and wherein the second relief pattern is selected from the negative tone developer resist.

4. The method of claim 1, wherein the third relief pattern, the second relief pattern and the first relief pattern are all in plane with each other.

5. The method of claim 1, wherein a single anti-reflective coating is used for the first exposure pattern, the second exposure pattern and the third exposure pattern.

6. The method of claim 1, wherein changes in physical properties includes increased cross-linking of the exposed surface such that the exposed surface of the first relief pattern increases in resistance to developing chemicals.

7. The method of claim 1, wherein the upper electrode comprises silicon, and wherein coupling negative polarity direct current power causes sputtering of silicon onto the first relief pattern creating a semi-conformal layer of silicon on the first relief pattern.

8. The method of claim 1, wherein the combined relief pattern includes intersecting features.

9. The method of claim 1, further comprising transferring the combined relief pattern into one or more underlying layers.

10. A method of patterning a substrate, the method comprising:
forming a first relief pattern on a substrate, the first relief pattern comprised of a first radiation-sensitive material;
causing the first relief pattern to become insoluble to predetermined developing agents;
forming a second relief pattern in plane with the first relief pattern, the second relief pattern comprised of a second radiation sensitive material;
causing the second relief pattern to become insoluble to predetermined developing agents;
forming a third relief pattern in plane with the first relief pattern and the second relief pattern such that the first relief pattern, the second relief pattern, and the third relief pattern form a combined relief pattern.

11. The method of claim 10, wherein the first relief pattern is selected from the group consisting of negative tone developer resist, positive tone developer resist, and alcohol-based resist; and
wherein the second relief pattern is selected from the group consisting of negative tone developer resist, positive tone developer resist, and alcohol-based resist.

12. The method of claim 10, wherein a single anti-reflective coating is used for forming the first relief pattern, the second relief pattern and the third relief pattern.

13. The method of claim 10, wherein the combined relief pattern includes features formed from one or more antispacer fabrication processes.

14. The method of claim 10, wherein causing the first relief pattern and the second relief pattern to become insoluble to predetermined developing agents includes treating the substrate with a flux of electrons.

15. A method for patterning a substrate, the method comprising:
forming a first layer of radiation-sensitive material on a substrate;
developing a first pattern in the first layer of radiation-sensitive material, the first pattern having been exposed via photolithography, wherein developing the first pattern results in a first relief pattern;
treating the first relief pattern with an electron flux formed by coupling negative polarity direct current power to an upper electrode in a plasma processing chamber, such that a protective layer is semi-conformally created on exposed surfaces of the first relief pattern, the electron flux sufficient to increase cross-linking of the first relief pattern;
forming a second layer of radiation-sensitive material on the substrate; and
developing a second pattern in the second layer of radiation-sensitive material, the second pattern having been exposed via photolithography, wherein developing the second pattern results in a second relief pattern having structures created between structures of the first relief pattern.
